(19) United States
(12) Patent Application Publication
(10) Pub. No.: US 2016/0268528 A1
(43) Pub. Date: Sep. 15, 2016

(54) PHOTOVOLTAIC DEVICE AND METHOD OF MANUFACTURE

(71) Applicant: Swansea University, Swansea (GB)

(72) Inventors: Trystan WATSON, Swansea (GB); David WORSLEY, Swansea (GB); Jeol TROUGHTON, Swansea (GB); Matthew CARNIE, Swansea (GB)

(21) Appl. No.: 15/031,949

(22) PCT Filed: Oct. 14, 2014
(86) PCT No.: PCT/GB2014/000412

§ 371 Date: Apr. 25, 2016

(30) Foreign Application Priority Data
Oct. 23, 2013 (GB) 1318737.2

(51) Int. Cl. H01L 51/42; H01L 51/00; H01L 51/44

(52) U.S. Cl. CPC H01L 51/4206; H01L 51/442; H01L 51/0021; H01L 51/0026

(57) ABSTRACT

A photovoltaic device is made by providing a substrate and forming a compact layer on the substrate. The compact layer is coated with a layer including metal oxide nanoparticles and perovskites. NIK radiation is used to cure the layer when exposed to light. There is also an electrode attached to the scaffold. The method allows for the manufacture of photovoltaic devices very efficiently and rapidly making it a very economical process.

### CROSS REFERENCE TO RELATED APPLICATIONS

This application is the U.S. national phase of international application Serial No. PCT/GB2014/000412, filed Oct. 14, 2014, which claims priority from international application Serial No. GB 1318737.2, filed Oct. 23, 2013, the contents of which are each incorporated herein in their entirety.

The invention relates to a photovoltaic device and a method of manufacture. In particular but not exclusively, this invention relates to the development of a rapid manufacturing process used to enhance the speed at which perovskite solar cells are fabricated.

### BACKGROUND OF THE INVENTION

Dye sensitised solar cells (DSCs) typically consist of a working electrode and a counter electrode. The working electrode comprises a conductive substrate coated with a semi-conductive nanoparticulate metal oxide such as Titanium dioxide (TiCh) and a dye adsorbed onto the metal oxide to sensitize it to a larger portion of the solar spectrum. Dye-sensitized solar cells (DSSCs) have losses, both from electron transfer from the dye (or absorber) into the TiC>2, which requires a certain “driving force,” and from dye regeneration from the electrolyte, which requires an over potential. Efforts have been made to reduce such losses in DSSCs.

An efficient solar cell must absorb over a broad spectral range, from visible to near-infrared (near-IR) wavelengths (350 to −950 nm), and convert the incident light effectively into charges. The charges must be collected at a high voltage with suitable current in order to do useful work. A simple measure of solar cell effectiveness at generating voltage is the difference in energy between the optical band gap of the absorber and the open-circuit voltage (Foc) generated by the solar cell under simulated air mass (AM) 1.5 solar illumination of 100 mW cm−2.

Inorganic semiconductor-sensitized solar cells have recently been used where a thin absorber layer of 2 to 10 nm in thickness, is coated upon the internal surface of a mesoporous TiC>2 electrode and then contacted with an electrolyte or solid-state hole conductor. These devices have achieved power conversion efficiencies of up to 6.3% However, in such systems there are low open circuit voltages which may be a result of the electronically disordered, low-mobility n-type TiC>2.

Perovskites are relatively underexplored in the area of solar cells and they provide a framework for binding organic and inorganic components into a molecular composite. It has been shown that layered perovskites based on organometal halides demonstrate excellent performance as light-emitting diodes and transistors with mobilities comparable to amorphous silicon.

The manufacture of solar cells based upon perovskites has several procedural steps which increases manufacturing costs because the process takes more time and energy. Typically the process involves providing a glass substrate having a conductive coating; usually fluorine doped tin oxide (FTO,) on one surface of the substrate. The FTO layer is coated with TiC>2, a sintered layer of metal oxide nanoparticles is coated on the TiC>2 and then there is heat treatment to drive off binders etc. to form a nanoporous film. The nanoporous film is coated with a precursor including a perovskite that again is heat treated so that the solution crystallizes to form a solid perovskite light absorber and electron transporter. As a final stage a hole transport layer and metal contacts are added.

The use of sintering to drive off binders etc. means that considerable time is taken to process the structure and also there is the increased cost of heating. The present invention seeks to overcome the problems of the prior art by providing a rapid and low temperature process in an extremely efficient photovoltaic device.

### SUMMARY OF THE INVENTION

According to a first aspect of the invention there is provided a method of making a photovoltaic device including:

providing a substrate;

forming a compact layer on the substrate;

characterised in that the compact layer is coated

a) with a precursor solution including metal oxide nanoparticles and perovskites, and said precursor solution is exposed to NIR radiation so the nanoparticles form a scaffold for the perovskites which can allow for light absorption and electron transportation in the compact layer when exposed to light, following which a conductor layer is attached to the scaffold or

b) a precursor solution including metal oxide is formed on the compact layer and treated with NIR radiation to form a scaffold and then a precursor solution containing perovskites is applied to the scaffold and exposed to NIR radiation so the perovskites can allow for light absorption and electron transportation in the compact layer when exposed to light, following which a conductor layer is attached to the scaffold.

It is envisaged that the NIR radiation is applied having a wavelength in the range of 700 and 2500 nm to the precursor solution. The NIR treatment heats the precursor solution so the perovskite precursor solution crystallizes to form the scaffold.

More preferably the NIR radiation is applied at a wavelength in the range of 800 to 1200 nm and more preferably in the range of 900 to 1050 nm.

It is envisaged that the compact layer is formed from Tin Oxide.

It is preferred that there is a transparent conducting oxide on the compact layer forming a layer between the substrate and the compact layer.

It is envisaged that the transparent conducting oxide is Fluorine doped Tin Oxide. It is preferred that the compact layer and the coating may be provided as a single integral layer.

It is preferred that the metal oxide nanoparticles are selected from one or more of titania, alumina or zirconia or a mixture thereof. In particular the nanoparticles are Al2O3.

It is preferred that the perovskite is an organometal halide. Typically the organometal halide is of the structure ABX3 where A and B are cations and X represents anions.

Preferably the perovskite is CH3NH3PBX3 where X is Chlorine or Bromine.

It is preferred that the percentage of metal oxide nanoparticles in the precursor solution containing the perovskite is 1 to 15% more preferable 1.5 to 12% and more particularly 2-7%.

Preferably the precursor solution is applied by spray pyrolysis in the presence of NIR or spin coating followed by MR treatment.

It is preferred that the substrate is an electrochemically inert material selected from glass, a metal, plastic or carbon or a combination thereof.

It is envisaged that if metal is used the substrate is selected from one or more of gold, or platinum or a combination thereof.

According to yet a further aspect of the invention there is provided a photovoltaic device formed by a method according to a first aspect of the invention where the photovoltaic device includes a substrate and a compact layer which is coated with a precursor solution including metal oxide nanoparticles that form a scaffold for perovskites which can act as a perovskite light absorber and electron transporter through the compact layer when exposed to light.

Preferably the perovskite is an organometal halide. Typically the organometal halide is of the structure ABX3 where A and B are cations and X represents anions.

It is envisaged that the perovskite is CH3NH3PBX3 where X is Chlorine or Bromine.

It is preferred that the substrate is deformable so that the photovoltaic device can be shaped.

It is preferred that the exposure to NIR is performed in 5 to 50 seconds and more preferably in 5 to 25 seconds.

It is envisaged that the NIR is at a wavelength of 800 to 1200 nm.

According to yet a further aspect of the invention there is provided solar cell including a photovoltaic device having a substrate and a compact layer which is includes a scaffold containing metal oxide nanoparticles that support and perovskites and said precursor solution having been exposed to NIR radiation to form a porous scaffold having a perovskite light absorber and electron transporter therein.

As can be seen the invention allows for the production of a photovoltaic device which is resistant to damage, which can be rapidly produced and which has improved efficiency than known devices.

### BRIEF DESCRIPTION OF THE DRAWINGS

An embodiment of the present invention will now be described by way of example only, with references to and as illustrated in the accompanying figures in which:

FIG. 1 shows: a schematic diagram of a perovskite device according to an embodiment of the invention;

### DETAILED DESCRIPTION OF THE INVENTION

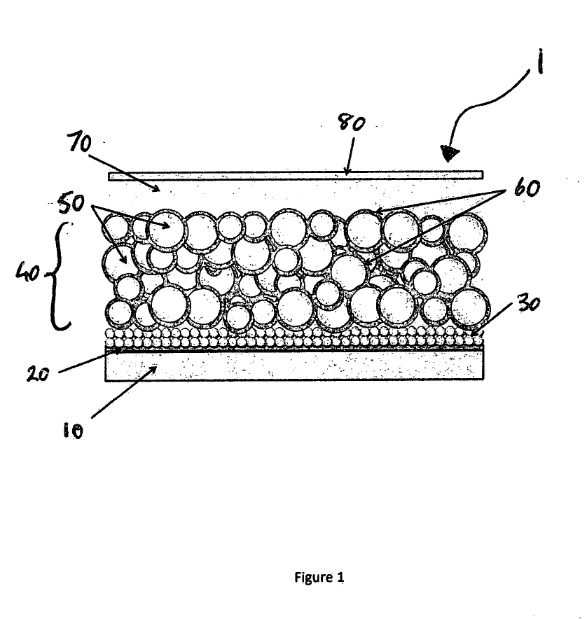

As can be seen in FIG. 1, a photovoltaic device that is to be used in a solar cell is generally shown as 1 and is formed of a glass substrate 10 which is coated with layer 20 provided as a semitransparent fluorine-doped tin oxide (FTO). A ZnO/HCl mix is used to remove any unwanted FTO. The glass is cleaned using water, surfactants, acetone, ethanol and dry N2. A compact layer 30, typically of TiO2 is then added and this acts as an anode. If glass is used the doped layer may be fluorine doped tin oxide on glass or indium tin oxide, which also may be provided on a plastic (e.g. PET or PEN) rather than glass. Having a plastic substrate means that the solar cells can be made flexible to they can be attached to a contoured surface.

The compact layer 30 may be applied to the glass in the form of a paste comprising a metal oxide in a binder and a solvent so that the oxide can be printed on a surface. The metal may also be a wide band gap metal oxide such as SnC>2 or ZnO or TiC>2. An advantage of SnC>2 is that it is easier to obtain good particle interconnectivity which will minimise resistive losses and increase the efficiency of the sensitized solar cell. An advantage of using ZnO is that ZnO nanoparticles are readily available at low material cost. There are however, several advantages are associated with using TiO2, namely, TiO2 is readily available, cheap, none-toxic and possesses good stability under visible radiation in solution, and an extremely high surface area suitable for dye adsorption. TiO2 is also porous enough to allow good penetration by the electrolyte ions, and finally, TiO2 scatters incident photons effectively to increase light harvesting efficiency. The compact TiC>2 blocking layer is 50 nm in thickness for TiC>2 cells and 100 nm for Al2O3 cells and this may be applied by either via spraying pyrolysis or spin coating using 127 pl Ti isopropoxide (99.99%) which is added to 845 pl ethanol. 7 pi HC1 (2 M) is added to the 845 pl ethanol whilst stirring.

The next layer that is added is the photoactive layer 40 which included nanoparticles 50 and a perovskite precursor 60. The nanoparticles form a scaffold for the perovskite. The nanoparticles can be applied to the compact layer simultaneously with the perovskites or the nanoparticles and perovskite can be applied sequentially with the nanoparticles providing a preformed scaffold for the perovskites. The level of loading of the precursor with the nanoparticles has an impact on the efficiency of the device. A good performance is achieved when the precursor has a nanoparticle loading of 5% by weight and performance rises up to this level and declines afterwards and the efficiency of the devices formed is more consistent.

If the nanoparticles are applied simultaneously with the perovskites then ideally the two solutions should be compatible. The nano-particles are sold as a suspension either in water or IPA (isopropyl alcohol). If the solvents are often incompatible with the perovskite precursor solution and so the nanoparticles should be suspended in the same solvent as the perovskite precursor solution. This is achieved via solvent exchange in a rotary evaporator. The preferred solvents for the organometal halide perovskite precursor solution are either DMF (N,N-Dimethylformamide) or y-butyrolactone. The precursor then consists of primary amine halide salt e.g. CH3NH3I (methyl ammonium lead iodide) and a lead halide salt e.g. PbCb (lead chloride) dissolved in the solvent in the correct stoichiometry.

If the scaffold is laid down first, a paste of alumina or titania containing nanoparticles is prepared by dilution of Dyesol AO (a commercially available titania paste that contains ethyl cellulose as binder and ethanol and terpineol as solvents) with ethanol. This is then deposited onto the blocking layer glass and spin coated to produce a thin ˜0.5-lum layer of Ti02/Al2O3. This material is then sintered at approximately by heating, typically at 100-120° C. for 40-60 or 450° C. for 30 minutes or by using NIR to produce a film containing the titania and/or alumina.

The perovskite is treated using NIR to rapidly crystallise the perovskites rapidly. The near-infrared region (NIR) of the electromagnetic spectrum is situated between the visible and the infrared at a wavelength of 700 nm to 2500 nm with a peak at around 1000 nm where typically polymer compounds do not have a strong absorbance. Where the nanoparticles and perovskite are applied simultaneously, the use of NIR radiation to rapidly cure, sinter and melt materials replace the need for a separate scaffold, effectively removing a processing step from the manufacturing process as outlined previously. NIR heating was achieved by moving the sample to be heated at a set speed, determined by the operator, under the emitters at a pre-set but variable power level. Altering the speed of the sample holder allowed the time of NIR exposure to the sample to be varied between 1.4 and 2.4 seconds. The NIR is provided by an NIR source 8 such as Adphos lamps.

To complete the photoactive layer, the perovskite-coated porous electrode was further filled with the hole transporter 70. Hole transport mediums (HTMs) have been developed as a solid alternative to liquid electrolytes. They function as an electron conduction path from a counter electrode to dyes desorbed onto the TiCh surface. To perform this function spiro-(OMeTAD) (2,2′7,7′-tetrakis (N,N-di-p-methoxyphenylamine)-9,9′-spirobifluorene) is the most popular hole transporter used showing decent charge carrier mobility. Here the electron transfer process occurs by a hole injection from the oxidised dye into the HTM. Electron conduction then transports the electron through the TiC>2 and hole through the HTM to an electrode 80. The electrode 80 forms a final layer and is typically a highly conductive metal provided typically as a silver or gold electrode or alternatively a grid can be printed on the photoactive layer to provide an electrode.

Typically charge collection in Al2O3-based devices was faster than in the TiCh-based sensitized devices by a factor of >10, indicating faster electron diffusion through the perovskite phase than through the n-type TiCh. Perovskites tend to form layered structures, with continuous two-dimensional metal halide planes perpendicular to the z axis and the lower dielectric organic components (methyl amine) between these planes. This quasi-two-dimensional confinement of the excitons can result in an increased exciton binding energy, which can be up to a few hundred millielectron volts.

The application of a mesostructured insulating scaffold upon which extremely thin films of n-type and p-type semiconductors are assembled, termed the meso-superstructured solar cell (MSSC), has proven to be extraordinarily effective with an n-type perovskite. The light absorption near the band edge can be enhanced through carefully engineered mesostructures and by optimising the nanoparticle to perovskite ratio. The loading of the perovskite precursor with a certain level of nanoparticles provides and optimised scaffold having a maximized surface area so that photovoltaic properties can be exploited as planar junction devices having efficiencies of around 1.8%. to Also because a low temperature process can be used, it is envisaged that the precursor can be simply painted onto a substrate and heat treated in situ to provide the solid perovskite light absorber and transporter. FIG. 3 shows efficiency data for MSSC's cured using MR at a) 40% power and b) 50% power. It can be seen that using NIR reaches close to the efficiency of oven cured standards, whilst enabling a rapid processing. The best average performing NIR settings cure the perovskite in under 8.5 seconds compared with 1 hour in an oven. Further optimising NIR lamp power and speed settings may bring the fast-cured device performance up to the same level as the oven-cured standard.

As can be seen, the invention has particular benefits in that it avoids having to use an expensive and time consuming processing step of sintering. Further, the perovskite grows into a continuous network so forming a scaffold for the solar cell and so provides a rapid and cost effective way of manufacturing solar cells.

Although the foregoing invention has been described in some detail by way of illustration and example, and with regard to one or more embodiments, for the purposes of clarity of understanding, it is readily apparent to those of ordinary skill in the art in light of the teachings of this invention that certain changes, variations and modifications may be made thereto without departing from the scope of the invention as described in the appended claims. Furthermore the invention is intended to cover not only individual embodiments that have been described but also combinations of the described embodiments.

1. A method of making a photovoltaic device including:
providing a substrate;
forming a compact layer on the the substrate;
characterised in that the compact layer is coated
a) with a precursor solution including metal oxide nanoparticles and a perovskite precursor, and said precursor solution is exposed to NIR radiation so the nanoparticles form a scaffold for the perovskites formed from the perovskite precursor which can allow for light absorption and electron transportation in the compact layer when exposed to light, following which a conductor layer is attached to the scaffold or
b) a precursor solution including metal oxide nanoparticles is formed on the compact layer and treated with NIR radiation to form a scaffold and then a perovskite precursor solution is applied to the scaffold and exposed to NIR radiation to form perovskites that can allow for light absorption and electron transportation in the compact layer when exposed to light, following which a conductor layer is attached to the scaffold.

2. A method according to claim 1, wherein the NIR radiation has a wavelength in the range of 700 and 2500 nm and more preferably in the range of 800 to 1200 nm and even more preferably in the range of 900 to 1050 nm.

3. A method according to claim 1, wherein the exposure to NIR is for 5 to 50 seconds.

4. A method according to claim 1, wherein the compact layer is formed from Tin Oxide.

5. A method according to claim 4, further comprising a transparent conducting oxide on the compact layer forming a layer between the substrate and the compact layer.

6. A method according to claim 5, wherein the transparent conducting oxide is Fluorine doped Tin Oxide.

7. A method according to claim 6, wherein the compact layer and the transparent conducting oxide is provided as a single integral layer.

8. A method according to claim 1, wherein the metal oxide nanoparticles are selected from one or more of titania, alumina or zirconia or a mixture thereof. In particular the nanoparticles are Al2O3.

9. A method according to claim 1, wherein the perovskite is an organometal halide.

10. A method according to claim 9, wherein the organometal halide is of the structure ABX₃ where A and B are cations and X represents anions.

11. A method according to claim 9, wherein the perovskite is CH₃NH₃PBX₃ where X is Chlorine or Bromine.

12. A method according to claim 1, wherein the percentage of metal oxide nanoparticles in the precursor solution containing the perovskite is 1 to 15%.

13. A method according to claim 1, wherein the precursor solution is applied by spray pyrolysis in the presence of NIR or spin coating followed by NIR treatment.

14. A method according to claim 1, wherein the substrate is selected from glass, a metal, plastic or carbon or a combination thereof.

15. A photovoltaic device formed by a method according to claim 1, wherein the photovoltaic device includes a substrate and a compact layer which is coated with a precursor solution including metal oxide nanoparticles that form a scaffold for perovskites which can act as a perovskite light absorber and electron transporter through the compact layer when exposed to light.

16. A photovoltaic device according to claim 15, wherein the perovskite is an organometal halide.

17. A photovoltaic device according to claim 16 wherein the perovskite is CH₃NH₃PBX₃ where X is Chlorine or Bromine.

18. A photovoltaic device according to claim 14, wherein the substrate is deformable so that the photovoltaic device can be shaped.

19. A solar cell including one or more photovoltaic devices according to claim 15, formed as an array connected to a power output.

20. A method according to claim 1, wherein the exposure to NIR is for 5 to 25 seconds.

21. A method according to claim 1, wherein the percentage of metal oxide particles in the precursor solution containing the perovskite is 1.5-12%.

22. A method according to claim 1, wherein the percentage of metal oxide particles in the precursor solution containing the perovskite is 2-7%.
